(19) United States
(12) Patent Application Publication
(10) Pub. No.: US 2019/0278465 A1
(43) Pub. Date: Sep. 12, 2019

(54) METHOD AND DEVICE FOR CONTROLLING DISPLAY SCREENS

(71) Applicant: SHENZHEN ROYOLE TECHNOLOGIES CO., LTD., Shenzhen (CN)

(72) Inventors: Li ZHOU, Shenzhen (CN); Xiangnan GU, Shenzhen (CN); Xuan ZHANG, Shenzhen (CN)

(21) Appl. No.: 16/422,085

(22) Filed: May 24, 2019

Related U.S. Application Data
(63) Continuation of application No. PCT/CN2016/112588, filed on Dec. 28, 2016.

(51) Int. Cl. G06F 3/0484; G01R 31/382; G06F 1/3203; H02J 7/00

(52) U.S. Cl. CPC G06F 3/04845; G01R 31/382; H02J 2007/005; H02J 7/0047; G06F 1/3203

(57) ABSTRACT

A method and device for controlling a display screen, wherein the method includes: obtaining remaining power information of a battery; determining screen size information corresponding to the remaining power information, wherein correspondence relations between the remaining power information and the screen size information are pre-established; and setting a current adjustable size of the display screen according to the screen size information.

### CROSS-REFERENCE TO RELATED APPLICATION(S)

This application is a continuation of PCT Patent Application No. PCT/CN2016/112588, filed on Dec. 28, 2016, contents of which are hereby incorporated in its entireties by reference.

### TECHNICAL FIELD

This disclosure relates to the field of electronic technology, and more particularly relates to a method and device for controlling a display screen.

### BACKGROUND

Flexible display screens are deformable display devices with advantages including small size, good portability, excellent image quality, and diversified displaying. In view of the above advantages, flexible display screens have been widely used in the industry, and are gradually applied to various types of terminal devices, such as smart phones, tablet computers, smart wearable devices, smart televisions, and the like. At present, a screen size of the flexible display screen, in some of terminal devices with high performance, can be controlled through software instructions.

However, on the one hand, in order to achieve light and thin characters of a flexible display terminal device, batteries with small size and limited capacity are usually adopted. On the other hand, in order to meet user requirements, a flexible display with a larger screen size is usually used, thereby resulting in relative high power consumption. The combination of two reasons makes the flexible display terminal devices have a poor power-on time capability.

### SUMMARY

Embodiments of the disclosure provide a method and device for controlling a display screen, which may control an adjustable size of the display screen according to a remaining power of a battery, thereby reducing power consumption and improving power-on time capability of the battery.

According to a first aspect, the embodiments of the present disclosure provide a method for controlling a display screen, comprising:

obtaining remaining power information of a battery;

determining screen size information according to the remaining power information, wherein correspondence relations between remaining power information and screen size information are pre-established; and

setting a current adjustable size of the display screen according to the screen size information.

According to a second aspect, the embodiments of the present disclosure provide a device for controlling a display screen, comprising:

an obtaining module, configured to obtain remaining power information of a battery;

a confirming module, configured to determine screen size information corresponding to the remaining power information, wherein correspondence relations between remaining power information and screen size information are pre-established; and

a setting module, configured to set a current adjustable size of the display screen according to the screen size information.

In the embodiment of the present disclosure, the remaining power information of the battery may be obtained to determine the screen size information corresponding to the remaining power information, wherein correspondence relations between remaining power information and screen size information are pre-established, and the current adjustable size of the display screen may be set according to the screen size information, thereby setting the adjustable size of the display screen according to the remaining power, reducing power consumption, and improving the power-on time capability of the battery.

### BRIEF DESCRIPTION OF THE ACCOMPANYING DRAWINGS

To describe the technology solutions in the embodiments of the present disclosure more clearly, the following briefly introduces the accompanying drawings required for describing the embodiments. Apparently, the accompanying drawings in the following description show merely some embodiments of the present disclosure, those of ordinary skill in the art may also derive other obvious variations based on these accompanying drawings without creative efforts.

FIG. 1 is a flow chart schematic diagram of a method for controlling a display screen, in accordance with an embodiment of the present disclosure;

FIG. 2 is a structural diagram illustrating a device from controlling a display screen, in accordance with an embodiment of the present disclosure;

FIG. 3 is a structural diagram of a display screen, in accordance with an embodiment of the present disclosure;

FIG. 4 is a schematic diagram of a liner relation, in accordance with an embodiment of the present disclosure;

FIG. 5 is one schematic diagram of a non-liner relation, in accordance with an embodiment of the present disclosure;

FIG. 6 is another schematic diagram of a non-liner relation, in accordance with an embodiment of the present disclosure.

### DETAILED DESCRIPTION OF ILLUSTRATED EMBODIMENTS

The technical solution in the embodiments of the present disclosure will be described clearly and completely hereinafter with reference to the accompanying drawings in the embodiments of the present disclosure. Apparently, the described embodiments are merely some but not all embodiments of the present disclosure. All other embodiments obtained by a person of ordinary skill in the art based on the embodiments of the present disclosure without creative efforts shall fall within the protection scope of the present disclosure.

A terminal device of the present disclosure may include, but not limited to, a smart phone, a tablet computer, a smart wearable device, a vehicle terminal, and the like which are equipped with flexible display screens.

A display screen of the present disclosure may be a flexible display screen, such as an OELD (Organic Light-Emitting Diode) flexible display screen, a screen size of which can be controlled by received software commands. For example, when a large image is displayed in the display screen, the screen size of the display screen can be increased. When a small image is displayed in the display screen, the screen size of the display screen may be decreased. The battery of the present disclosure may be a storage battery capable of charging and discharging.

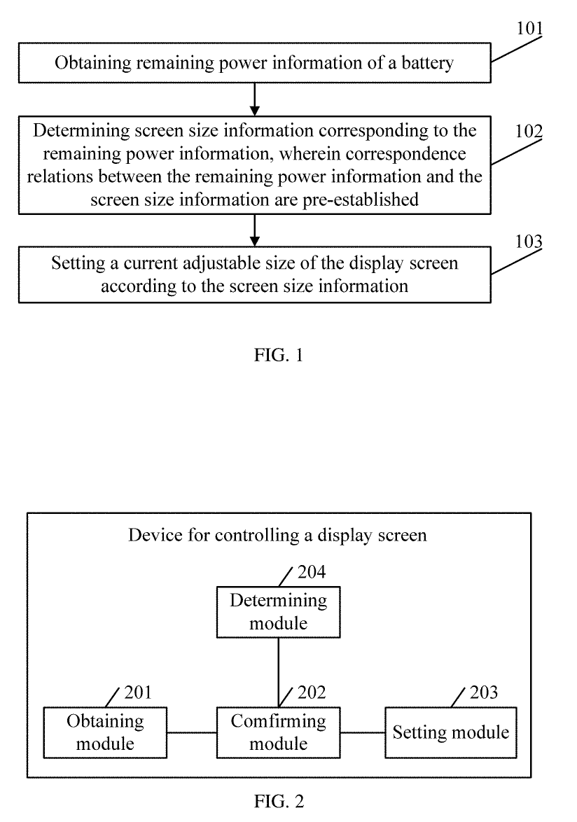

Referring to FIG. 1, which illustrates one embodiment of the present disclosure of a flow chart schematic diagram of a method for controlling the display screen. The method for controlling the display screen of the present embodiment includes:

At block 101, the terminal device obtains remaining battery information of the battery.

In one implementation, the terminal device may obtain the remaining battery information of the battery and monitor a remaining power of the battery in real time by accessing a Power Management Integrated Circuits (PMIC). Therein, the PMIC is used to perform a power conversion, power distribution, power detection and other power managements of the battery.

In some embodiments, the remaining power information may be a remaining power ratio of the battery. Correspondingly, an operation of the terminal device obtaining the remaining power information includes:

At step 1, the terminal device detects the remaining power of the battery. Specifically, the terminal device detects a specific value of the remaining power of the battery through the PMIC, such as 1200 mA.

At step 2, the terminal device calculates the ratio, Epercent, of CurrentElectricity to MaxElectricity. Therein, the Epercent represents the remaining power ratio of the battery, the CurrentElectricity the remaining power of the battery, the MaxElectricity a total power of the battery. Specifically, the terminal device can query the total power of the battery through the PMIC, and further calculate the remaining power ratio of the battery according to the detected remaining power and the total power. For example, if the CurrentElectricity is 1200 mA, and the MaxElectricity is 4800 mA, that is, the CurrentElectricity=1200 mA, and MaxElectricity=4800 mA, then, the Epercent is calculated as 25%, that is, the Epercent=CurrentElectricity/MaxElectricity=1200/4800=25%.

In some embodiments, the screen size of the display screen is only decreased to save power when the battery is at a low power. In order to avoid affecting a normal use for the user, it is not necessary to perform subsequent processes when the power of the battery is normal. In one embodiment, the terminal device firstly determines whether the remaining power is lower than a first predefined threshold according to the remaining power information. If the remaining power is lower than the first predefined threshold, step of block 102 may be performed; otherwise, no step would be performed. Therein, the first predefined threshold may be pre-set by the device manufacturer before leaving factory, or may be set by the user after leaving factory, which is not specifically limited herein.

For example, if the first predefined threshold is 30%, and the current remaining power ratio is 25%, then, the step of block 102 is performed after determining that the remaining power ratio is lower than the first predefined threshold. For another example, if the first predefined threshold is 30%, and the current remaining power ratio is 35%, it is determined that the remaining power ratio is higher than the first predefined threshold, and no step would be performed.

In some embodiment, since the remaining power of the battery increases when the battery is in a charging state, in order to avoid affecting the normal use for the user, the screen size can be restored again when the battery is in the charging state, and the subsequent steps should be performed. In one embodiment, when the terminal device is in the charging state, the terminal device determines whether the remaining power is higher than a second predefined threshold according to the remaining power information. If the remaining power is higher than the second predefined threshold, step of block 102 is performed; otherwise, the terminal device does not do anything. Similarly, the second predefined threshold can be pre-set by the device manufacturer before leaving factory, or may be set by the user after leaving factory, which is not specifically limited herein. Optionally, the second predefined threshold may be equal to the first predefined threshold, or may not be equal to the first predefined threshold, which is not limited herein.

For example, if the second predefined threshold is 20%, and the current remaining power ratio is 25%, then, step of block 102 is performed after determining that the remaining power ratio is higher than the second predefined threshold. For another example, if the second predefined threshold is 20%, and the current remaining power ratio is 15%, the remaining power ratio is lower than the second predefined threshold, and no processing would be performed.

At block 102, the terminal device determines screen size information corresponding to the remaining power information, wherein correspondence relations between the remaining power information and the screen size information are pre-established.

Therein, the screen size information may be a current adjustable size of the display screen.

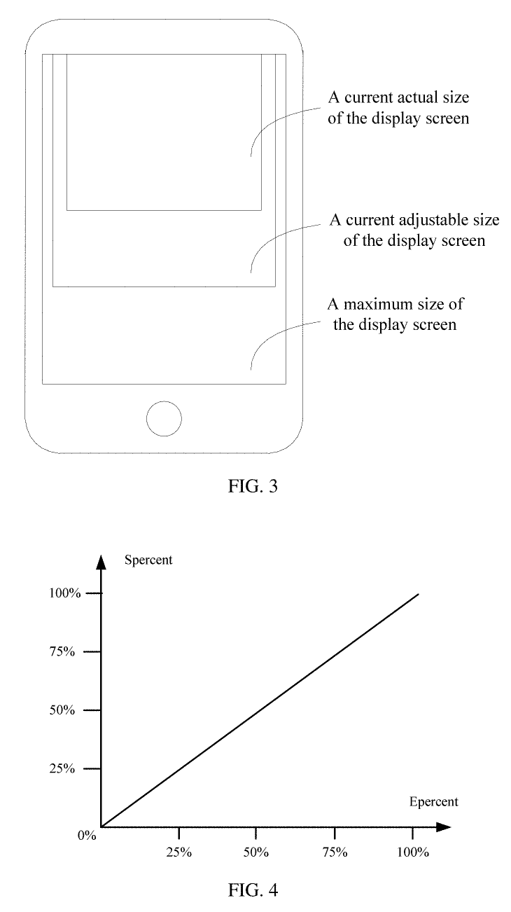

In one implementation, the current adjustable size of the display screen may be a current maximum adjustable size. The current maximum adjustable size refers to a maximum size to which the display screen can be stretched. The maximum size can be a constant value, such as 8 inches, that is the display screen can only stretch to 8 inches. As shown in FIG. 3, a current actual size, the current adjustable size, and the maximum size of the display screen are marked on the display screen. The maximum size is determined by physical characteristics of the display screen. The maximum adjustable size can be changed as long as it is not larger than the maximum size. The actual size can only be changed between a minimum size (for example, it can be a predefined initial value) and the maximum adjustable size.

Correspondingly, an operation that the terminal device determines the screen size information corresponding to the remaining power information is shown as follows:

At step 1, the terminal device determines Spercent corresponding to the Epercent. Therein, the Spercent represents a proportion of the current adjustable size of the display screen, wherein correspondence relations between Epercent and Spercent are pre-established.

In some embodiments, the pre-established correspondence relations between Epercent and Spercent include linear relations and non-linear relations.

In some embodiments, when the pre-established correspondence relations between the Epercent and the Spercent are the linear relation, the linear relations are Epercent=k*Spercent, wherein the k is a predefined constant coefficient and is a positive number being not greater than 1. For example, assuming k=1, the correspondence relation between the Epercent and the Spercent can be shown as FIG. 4. The terminal device directly sets the remaining power ratio as the proportion of the current adjustable size of the display screen.

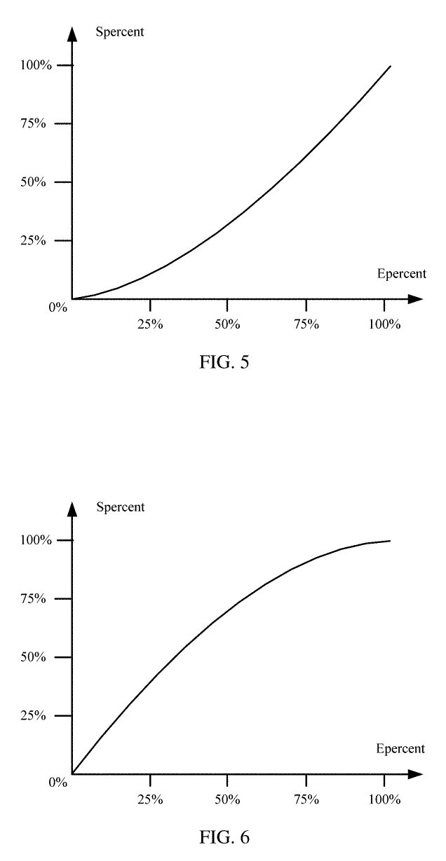

In some embodiments, when the pre-established correspondence relations between Epercent the Spercent are non-linear relations, the non-linear relations are Epercent=k*Spercent² or Epercent=k*\sqrt{Spercent}. Similarly, the k is a predefined constant coefficient and is a positive number being not greater than 1. For example, assuming k=1, the correspondence relations between Epercent and Spercent can be shown as in FIG. 5 or shown as in FIG. 6. As shown in FIG. 5, the higher the remaining power ratio is, the greater impact on the current adjustable size of the display screen is. As shown in FIG. 6, the smaller the remaining power ratio is, the greater impact on the current adjustable size of the display screen is.

At step 2, the terminal device calculates a product of multiplication, CurrentScreenSize, of Spercent and MaxScreenSize. The CurrentScreenSize represents the current adjustable size of the display screen, and the MaxScreenSize represents the maximum size of the display screen. For example, if a determined Spercent is 20%, and the MaxScreenSize is 100, that is, the Spercent=20% and the MaxScreenSize=100, the terminal device can calculate the current adjustable size of the display screen, that is CurrentScreenSize=20.

In some embodiments, the terminal device can perform the operation of determining the screen size information corresponding to the remaining power information continuously or non-continuously. Specifically, when it is performed continuously, the terminal device determines the corresponding Spercent according to Epercent in real time. Specifically, when the non-continuous operations are performed, some nodes of the remaining power ratio may be predefined, such as 50%, 40%, 30%, 20%, and 10%, and the terminal device determines the Spercent as each of the nodes being detected.

At block 103, the terminal device sets the current adjustable size of the display screen according to the screen size information.

In one implementation, the terminal device may set the current adjustable size of the display screen according to the screen size information and a current display content of the display screen, comprehensively.

In some embodiments, the current adjustable size of the display screen can be the current maximum adjustable size, that is the maximum size to which the display screen can be stretched as descripted above, and the terminal device can directly set the calculated CurrentScreenSize as the current maximum display screen. That is to say, it is possible to realize that when the remaining power is reduced, the maximum adjustable size of the display screen becomes smaller, and when the remaining power is increased, the maximum adjustable size of the display screen becomes larger.

In some embodiments, the current adjustable size of the display screen may also be a stretchable size range, and can be a constant value interval. For example, when the remaining power ratio exceeds to a predefined value (such as 50%), the stretchable size range of the display screen is [3 inches, 10 inches]. When the remaining power ratio is less than the predefined value, the stretchable size range of the display screen is (0 inches, 6 inches), and so on.

In some embodiments, the current adjustable size of the display screen includes at least two adjustable sizes, and the terminal device can switch the display screen between the at least two adjustable sizes according to an operation instruction inputted from a user. Thus, the screen size of the display screen can be set conveniently, to fit an application that the user is using. For example, if the current adjustable size of a set display screen includes three adjustable sizes a, b, and c, wherein a<b<c. The screen size of the display screen can be switched between a, b, and c by the terminal device according to the operation instruction inputted from the user. For the three adjustable sizes, the terminal device can set first values of the three adjustable sizes corresponding to the current remaining power ratio according to second values of the three adjustable sizes corresponding to the total power (i.e., the remaining power ratio is 100%). For example, if the three adjustable sizes corresponding to the total power are A, B, and C, where A<B<C, and the current remaining power ratio is 50%, then the terminal device sets the current three adjustable sizes to be a=0.5*A, b=0.5*B, c=0.5*C. That is, the three adjustable sizes can be scaled in equal proportions.

In embodiments of the present invention, the terminal device firstly obtains the remaining battery information of the battery, and then determines the screen size information corresponding to the remaining battery information, wherein the correspondence relations between the remaining battery information and the screen size information are pre-established, and then sets the current adjustable size of the display screen according to the screen size information. Thus, the current adjustable size of the display screen can be set according to the remaining battery capacity of the battery. Especially, when the remaining battery capacity is low, the adjustable size of the display screen can be decreased, to reduce power consumption and improve the power on time capacity of the battery. Furthermore, during the process of charging the battery, the adjustable size of the display screen can be increased when the remaining power of the battery is high, to ensure a good experience when the user uses the display screen.

Referring to FIG. 2, which illustrates one embodiment of the present disclosure of a structural diagram of a device for controlling a display screen. The device for controlling the display screen of the present disclosure includes:

An obtaining module 201 is configured to obtain remaining battery information of a battery.

A confirming module 202 is configured to determine screen size information corresponding to the remaining battery information, wherein correspondence relations of the remaining battery information and the screen size information are pre-established.

A setting module 203 is configured to set a current adjustable size of the display screen of the display screen according to the screen size information.

In some implementations, the obtaining module 201 obtains the remaining battery information of the battery and monitors the remaining power of the battery through a Power Management Integrated Circuits (PMIC). Therein, the PMIC is used to perform a power conversion, power distribution, power detection and other power managements of the battery.

In some embodiments, the remaining power information may be a remaining power ratio of the battery. Correspondingly, operations of the obtaining module 201 obtaining the remaining power information include:

The obtaining module 201 detects the remaining power of the battery.

Specifically, the obtaining module 201 detects a specific value of the remaining power of the battery through the PMIC, such as 1200 mA.

The obtaining module 201 calculates a ratio, Epercent, of CurrentElectricity to MaxElectricity. Therein, the Epercent represents the remaining power ratio of the battery, the CurrentElectricity the remaining power of the battery, and the MaxElectricity a total power of the battery. Specifically, the obtaining module 201 can query the total power of the battery through the PMIC, and further calculate the remaining power ratio of the battery according to the detected remaining power and the total power. For example, if the CurrentElectricity is 1200 mA, and the MaxElectricity is 4800 mA, that is, the CurrentElectricity=1200 mA, and MaxElectricity=4800 mA, then, the Epercent is calculated as 25%, that is, the Epercent=CurrentElectricity/MaxElectricity=1200/4800=25%.

In other embodiments, the device can further comprise a determining module 204, wherein:

The determining module 204 is configured to determine whether the remaining power of the battery is lower than a first predefined threshold.

The confirming module 202 is configured to:

determine the screen size information corresponding to the remaining battery information when the remaining power is lower than the first predefined threshold.

That is, the screen size of the display screen is only decreased to save power when the battery is at a low power. In one embodiment, the determining module 204 firstly determines whether the remaining power of the battery is lower than the first predefined threshold. If the remaining power is lower than the first predefined threshold, then, the confirming module 202 determines the screen size information corresponding to the remaining power information. Otherwise, the confirming module 202 would perform nothing. Therein, the first predefined threshold may be pre-set by the device manufacturer before leaving factory, or may be set by the user after leaving factory, which is not specifically limited herein.

For example, if the first predefined threshold is 30%, and the current remaining power ratio is 25%, then, the determining module 204 determines that the remaining power is lower than the first predefined threshold, the confirming module 202 determines the screen size information corresponding to the remaining power information. For another example, if the first predefined threshold is 30%, and the current remaining power ratio is 35%, it is determined, by the determining module 204, that the remaining power ratio is higher than the first predefined threshold, the confirming module 202 would perform nothing.

In some embodiments, since the remaining power of the battery increases when the battery is in a charging state, in order to avoid affecting the normal use for the user, the screen size can be restored again when the battery is in the charging state. In one embodiment, when the terminal device is in the charging state, the determining module 204 determines whether the remaining power is higher than a second predefined threshold according to the remaining power information. If the remaining power is higher than the second predefined threshold, the confirming module 202 determines the screen size information corresponding to the remaining power information; otherwise, the confirming model 202 would perform nothing. Similarly, the second predefined threshold can be pre-set by the device manufacturer before leaving factory, or may be set by the user after leaving factory, which is not specifically limited herein. Optionally, the second predefined threshold may be equal to the first predefined threshold, or may not be equal to the first predefined threshold, which is not limited herein.

For example, if the second predefined threshold is 20%, and the current remaining power ratio is 25%, the confirming module 202 determines the screen size information corresponding to the remaining power information. For another example, if the second predefined threshold is 20%, and the current remaining power ratio is 15%, the determining module 204 determines that the remaining power ratio is lower than the second predefined threshold, the confirming module 202 would perform nothing.

In some embodiments, the screen size information may a current adjustable size. The current adjustable size of the display screen may be a current maximum adjustable size. The current maximum adjustable size refers to a maximum size that the display screen can be stretched. The maximum size can be a constant value, such as 8 inches, that is the display screen can only stretch up to 8 inches. As shown in FIG. 3, a current actual size, the current adjustable size, and the maximum size of the display screen are marked on the display screen. The maximum size is determined by physical characteristics of the display screen. The maximum adjustable size can be changed as long as it is not larger than the maximum size. The actual size can only be changed between a minimum size (for example, it can be a predefined initial value) and the maximum adjustable size.

Consequently, operations of the confirming module 202 determining the screen size information corresponding to the remaining power information is shown as follows:

The confirming module 202 determines Spercent corresponding to the Epercent. Therein, the Spercent represents a proportion of a current adjustable size of the display screen, wherein correspondence relations between the Epercent and the Spercent are pre-established.

In some embodiments, the pre-established correspondence relations between the Epercent and the Spercent include linear relations and non-linear relations.

In some embodiments, when the pre-established correspondence relations between the Epercent and the Spercent are the linear relations, the linear relations are Epercent=k*Spercent, wherein the k is a predefined constant coefficient and is a positive number being not greater than 1. For example, assuming k=1, the correspondence relation between the Epercent and the Spercent can be shown as FIG. 4. The confirming module 202 directly sets the remaining power ratio as the proportion of the current adjustable size of the display screen.

In some embodiments, when the pre-established correspondence relations between the Epercent and the Spercent are non-linear relations, the non-linear relations are Epercent=k*Spercent² or Epercent=k*\sqrt{Spercent}. Similarly, the k is a predefined constant coefficient and is a positive number being not greater than 1. For example, assuming k=1, the correspondence relation between the Epercent and the Spercent can be shown as in FIG. 5 or shown as in FIG. 6. As shown in FIG. 5, the higher the remaining power ratio is, the greater impact on the current adjustable size of the display screen is. As shown in FIG. 6, the smaller the remaining power ratio is, the greater impact on the current adjustable size of the display screen is.

The confirming module 202 calculates a product of multiplication, CurrentScreenSize, of the Spercent and MaxScreenSize. The CurrentScreenSize represents the current adjustable size of the display screen, and the MaxScreenSize the maximum size of the display screen. For example, if a determined Spercent is 20%, and the MaxScreenSize is 100, that is the Spercent=20% and the MaxScreenSize=100, the terminal device can calculate the current adjustable size of the display screen, that is CurrentScreenSize=20.

In some embodiments, the confirming module 202 may perform operations of determining the screen size information corresponding to the remaining power information continuously or non-continuously. Specifically, when it is performed continuously, the confirming module 202 determines the corresponding Spercent according to Epercent in real time. Specifically, when the non-continuous operations are performed, some nodes of the remaining power ratio may be predefined, such as 50%, 40%, 30%, 20%, and 10%, and the confirming module 202 determines the Spercent as each of the nodes being detected.

In one implementation, the setting module 203 can set the current adjustable size of the display screen according to the screen size information, and a current display content of the display screen, comprehensively.

In some embodiments, the current adjustable size of the display screen can be the current maximum adjustable size, that is the maximum size to which the display screen can be stretched as descripted above, and the adjusting module 203 can directly set the calculated CurrentScreenSize as the current maximum display screen. That is to say, it is possible to realize that when the remaining power is reduced, the maximum adjustable size of the display screen becomes smaller, and when the remaining power is increased, the maximum adjustable size of the display screen becomes larger.

In some embodiments, the current adjustable size of the display screen may also be a stretchable size range, and can be a constant value interval. For example, when the remaining power ratio exceeds to a predefined value (such as 50%), the stretchable size range of the display screen is [3 inches, 10 inches]. When the remaining power ratio is less than the predefined value, the stretchable size range of the display screen is (0 inches, 6 inches), and so on.

In some embodiments, the current adjustable size of the display screen includes at least two adjustable sizes, and the adjusting module 203 can switch the display screen between the at least two adjustable sizes according to an operation command inputted from a user. Thus, the screen size of the display screen can be adjusted conveniently, to fitting an application that the user is using. For example, if the current adjustable size of the set display screen includes three adjustable sizes a, b, and c, wherein a<b<c. The screen size of the display screen can be switched between a, b, and c by the adjusting module 203, according to an operation instruction inputted from the user. For the three adjustable sizes, the adjusting module 203 can set first values of the three adjustable sizes corresponding to the current remaining power ratio according to second values of the three adjustable sizes corresponding to the total power (i.e., the remaining power ratio is 100%). For example, if the three adjustable sizes corresponding to the total power are A, B, and C, where A<B<C, and the current remaining power ratio is 50%, then the adjusting module 203 sets the current three adjustable size to be a=0.5*A, b=0.5*B, c=0.5*C. That is, the three adjustable sizes can be scaled in equal proportions.

In embodiments of the present invention, the obtaining module 201 firstly obtains the remaining battery information of the battery, and then, the confirming module 202 determines the screen size information corresponding to the remaining battery information, wherein the correspondence relations between the remaining battery information and the screen size information are pre-established, and then, the setting module 203 sets the adjustable size of the display screen according to the screen size information. Thus, the current adjustable size of the display screen can be set according to the remaining battery capacity of the battery. Especially, when the remaining battery capacity is low, the adjustable size of the display screen can be decreased, to reduce power consumption and improve the power on time capacity of the battery. Furthermore, during the process of charging the battery, the adjustable size of the display screen can be increased when the remaining power of the battery is high, to ensure a good experience when the user uses the display screen.

It is to be noted that, for the sake of simplicity, the foregoing method embodiments are described as a series of action combinations, however, it will be appreciated by those skilled in the art that the present disclosure is not limited by the sequence of actions described. According to the present disclosure, certain steps may be performed in other order or simultaneously. Besides, it will be appreciated by those skilled in the art that the embodiments described in the specification are exemplary embodiments and the actions and modules involved are not necessarily essential to the present disclosure.

It will be understood by those of ordinary skill in the art that all or part of the operations of the various methods of the embodiments described above may be accomplished by means of a program to instruct associated hardware, such as at least one processor. The program may be stored in a computer-readable memory, which may include a flash memory, a read-only memory (ROM), a random-access memory (RAM), a disk or a compact disc (CD), and so on.

The above is a preferred embodiment of the present disclosure, and it should be noted that those skilled in the art may make some improvements and modifications without departing from the principle of the present disclosure, and these improvements and modifications also are the protection scope of the present disclosure.

What is claimed is:

1. A method for controlling a display screen, the method comprising:
obtaining remaining power information of a battery;
determining screen size information corresponding to the remaining power information, wherein first correspondence relations between the remaining power information and the screen size information are pre-established; and
setting a current adjustable size of the display screen according to the screen size information.

2. The method of claim 1, further comprising: after obtaining the remaining power information of the battery:
determining whether a remaining power of the battery is lower than a first predefined power threshold based on the remaining power information of the battery;
performing step of determining the screen size information corresponding to the remaining power information when the remaining power of the battery is lower than the first predefined power threshold.

3. The method of claim 1, further comprising: after the obtaining the remaining power information of the battery:
determining whether the remaining power of the battery is higher than a second predefined battery threshold based on the remaining power information of the battery when the battery is in a charging state;
performing step of determining the screen size information corresponding to the remaining power information when the remaining power of the battery is higher than the second predefined power threshold.

4. The method of claim 1, wherein setting the current adjustable size of the display screen according to the screen size information comprises:
setting a maximum adjustable size of the display screen according to the screen size information, wherein the maximum adjustable size is a maximum size to which the display screen is capable of stretching.

5. The method of claim 1, wherein setting the current adjustable size of the display screen according to the screen size information comprises:
setting at least two current adjustable sizes of the display screen according to the screen size information, wherein the at least two adjustable sizes are not greater than a maximum size to which the display screen is capable of stretching.

6. The method of claim 1, wherein obtaining the remaining power information of the battery comprises:
detecting a remaining power of the battery;
calculating a ratio, Epercent, of CurrentElectricity to MaxElectricity, wherein the CurrentElectricity represents the remaining power of the battery, the MaxElectricity a total power of the battery, the Epercent the remaining power ratio of the battery;
wherein setting the current adjustable size of the display screen according to the screen size information comprises:
determining Spercent corresponding to the Epercent, wherein the Spercent represents a proportion of the current adjustable size of the display screen, and second correspondence relations between Epercent and Spercent are pre-established;
calculating a product of multiplication, CurrentScreenSize, of the Spercent and MaxScreenSize, wherein the MaxScreenSize represents a maximum size of the display screen, and the CurrentScreenSize the current adjustable size of the display screen.

7. The method of claim 6, wherein the second pre-established correspondence relations between the Epercent and the Spercent comprise linear relations and non-linear relations.

8. The method of claim 7, wherein the second pre-established correspondence relations between the Epercent and the Spercent comprise:
Epercent=k*Spercent; or
Epercent=k*Spercent²; or
Epercent=k*\sqrt{Spercent};
Wherein the k is a predefined constant coefficient and is a positive number being not greater than 1.

9. The method of claim 1, wherein the display screen is a flexible display screen.

10. A device for controlling a display screen, comprising:
at least one processor; and
a computer readable storage, coupled to the at least one processor and storing at least one computer executable instruction thereon, which when executed by the at least one processor, cause the at least one processor to carry out actions, comprising:
obtaining remaining power information of a battery;
determining screen size information corresponding to the remaining power information, wherein first correspondence relations between the remaining power information and the screen size information are pre-established; and
setting a current adjustable size of the display screen according to the screen size information.

11. The device of claim 10, wherein the at least one processor is further caused to carry out actions, comprising:
determining whether a remaining power of the battery is lower than a first predefined power threshold based on the remaining power information of the battery;
performing step of determining the screen size information corresponding to the remaining power information when the remaining power of the battery is lower than the first predefined power threshold.

12. The device of claim 10, wherein the at least one processor is further caused to carry out actions, comprising:
determining whether the remaining power of the battery is higher than a second predefined battery threshold based on the remaining power information of the battery when the battery is in a charging state;
performing step of determining the screen size information corresponding to the remaining power information when the remaining power of the battery is higher than the second predefined power threshold.

13. The device of claim 10, wherein the at least one processor carrying out the action of setting the current adjustable size of the display screen according to the screen size information, comprises:
setting a current maximum adjustable size of the display screen according to the screen size information, wherein the maximum adjustable size is a maximum size to which the display screen is capable of stretching.

14. The device of claim 10, wherein the at least one processor carrying out the action of setting the current adjustable size of the display screen according to the screen size information, comprises:
setting at least two current adjustable sizes of the display screen according to the screen size information, wherein the at least two adjustable sizes are not greater than a maximum size to which the display screen is capable of stretching.

15. The device of claim 10, wherein the at least one processor carrying out the action of obtaining the remaining power information of the battery, comprises:
detecting a remaining power of the battery;
calculating a ratio, Epercent, of CurrentElectricity to MaxElectricity, wherein the CurrentElectricity represents the remaining power of the battery, the MaxElectricity a total power of the battery, the Epercent the remaining power ratio of the battery;
the at least one processor carrying out the action of setting the current adjustable size of the display screen according to the screen size information, comprising:
determining Spercent corresponding to the Epercent, wherein the Spercent represents a proportion of the current adjustable size of the display screen, and second correspondence relations between Epercent and Spercent are pre-established;
calculating a product of multiplication, CurrentScreenSize, of the Spercent and MaxScreenSize, wherein the MaxScreenSize represents a maximum size of the display screen, and the CurrentScreenSize the current adjustable size of the display screen.

16. The device of claim 15, wherein the second pre-established correspondence relations between the Epercent and the Spercent comprise linear relations and non-linear relations.

17. The device of claim 16, wherein the second pre-established correspondence relations between the Epercent and the Spercent comprise:
Epercent=k*Spercent; or
Epercent=k*Spercent²; or
Epercent=k*\sqrt{Spercent};
Wherein the k is a predefined constant coefficient and is a positive number being not greater than 1.

18. The device of claim 10, wherein the display screen is a flexible display screen.

19. A non-transitory computer-readable storage medium storing computer programs which, when executed by a processor, cause the processor to carry out actions comprising:
obtaining remaining power information of a battery;
determining screen size information corresponding to the remaining power information, wherein correspondence relations between the remaining power information and the screen size information are pre-established; and
setting current adjustable size of the display screen according to the screen size information.

20. The non-transitory computer-readable storage medium of claim 19, wherein the computer programs executed by the processor to carry out the action of setting the current adjustable size of the display screen according to the screen size information, comprise:
setting a maximum adjustable size of the display screen according to the screen size information, wherein the maximum adjustable size is a maximum size to which the display screen is capable of stretching.
